(19) United States
(12) Patent Application Publication
(10) Pub. No.: US 2025/0289997 A1
(43) Pub. Date: Sep. 18, 2025

(54) QUANTUM DOT COMPOSITION, QUANTUM-DOT-COMPOSITION-CONTAINING LIQUID, LIGHT-EMITTING ELEMENT, LIGHT-EMITTING DEVICE, AND METHOD FOR PRODUCING QUANTUM DOT COMPOSITION

(71) Applicant: Sharp Display Technology Corporation, Kameyama City, Mie (JP)

(72) Inventor: Takahiro DOE, Kameyama City, Mie (JP)

(21) Appl. No.: 18/702,602

(22) PCT Filed: Jan. 27, 2022
(86) PCT No.: PCT/JP2022/003031

§ 371 Date: Apr. 18, 2024

(51) Int. Cl. C09K 11/02; B82Y 20/00; B82Y 40/00; H10K 50/115

(52) U.S. Cl. CPC C09K 11/025; B82Y 20/00; B82Y 40/00; H10K 50/115

(57) ABSTRACT

A QD composition includes: a QD; and at least one metal compound selected from the group consisting of a metal-fluoro complex, a metal-fluoro complex containing a hydroxy group, and a metal oxide containing fluorine. A complex stability constant of the metal-fluoro complex of the at least one metal element contained in the metal compound is larger than a complex stability constant of the metal-fluoro complex of the at least one metal element contained in the quantum dot, within a range of 0.1 or more and 20.0 or less.

### TECHNICAL FIELD

The present disclosure relates to a quantum dot composition, a quantum-dot-composition-containing liquid, a light-emitting element, a light-emitting device, and a method for producing a quantum dot composition.

### BACKGROUND ART

Patent Document 1 discloses a quantum dot composition having a very stable nanostructure, and containing a quantum dot and at least one fluoride-containing ligand bonded to a surface of the quantum dots and selected from the group consisting of fluorozincate, tetrafluoroborate, and hexafluorophosphate.

### CITATION LIST

### Patent Literature

[Patent Document 1] Japanese Unexamined Patent Application Publication No. 2020-180278

### SUMMARY

### Technical Problems

However, fluorozincate exhibits a relatively weak zinc (Zn)-fluorine (F) bond in a complex. For this reason, fluorozincate has a strong tendency for F in the complex to be substituted with an OH group, and is unstable to the substitution with the OH group. Fluorozincate is more likely to form a Zn—OH bond than a Zn—F bond, and reacts with a OH group to readily form Zn(OH)₂.

In Patent Document 1, at least one selected from the group consisting of fluorozincate, tetrafluoroborate, and hexafluorophosphate is unconditionally used as the fluoride-containing ligand. However, when a quantum dot contains, for example, Zn as described in Patent Document 1, if fluorozincate is used as the fluoride-containing ligand, the OH group is found near a surface of the quantum dot. As a result, the quantum dot shows a deterioration in characteristics and a decrease in reliability. For this reason, fluorozincate is not preferable in view of long-term reliability of an element containing the quantum dot composition. Furthermore, when the OH group is found near the surface of the quantum dot and the quantum dot is exposed to an electric field in which a dipole moment of the OH group is generated, an exciton of the quantum dot might be separated into an electron and a hole, and could be deactivated and quenched. Moreover, Zn(OH)₂ is an insulator, and a decrease in electrical conductivity reduces carrier injection properties. Hence, when fluorozincate is used as the fluoride-containing ligand, light emission efficiency of the quantum dot decreases.

In contrast, tetrafluoroborate and hexafluorophosphate are very stable, and do not sufficiently function as sacrificial layers for a OH group. Hence, if tetrafluoroborate or hexafluorophosphate is used as the fluoride-containing ligand, the OH group reaching the surface of the quantum dot preferentially bonds to, for example, Zn contained in a surface layer of the quantum dot. As a result, also in this case, the OH group is found near the surface of the quantum dot. Thus, the quantum dot shows a deterioration in characteristics, and the resulting decrease in reliability and light emission efficiency.

An aspect of the present disclosure is devised in view of the above problems, and sets out to provide a quantum dot composition that exhibits high stability to a OH group and excels in long-term reliability and light emission efficiency. The present disclosure also provides a quantum-dot-composition-containing liquid, a light-emitting element, a light-emitting device, and a method for producing a quantum dot composition.

### Solution to Problems

In order to solve the above problems, a quantum dot composition according to an aspect of the present disclosure includes: a quantum dot; and at least one metal compound selected from the group consisting of a metal-fluoro complex, a metal-fluoro complex containing a hydroxy group, and a metal oxide containing fluorine. Each of the metal compound and the quantum dot contains at least one metal element. A complex stability constant of the metal-fluoro complex of the at least one metal element contained in the metal compound in an aqueous solution is larger than a complex stability constant of the metal-fluoro complex of the at least one metal element contained in the quantum dot in the aqueous solution. The complex stability constant of the metal-fluoro complex of the at least one metal element contained in the metal compound in the aqueous solution is within a range of 0.1 or more and 20.0 or less.

In order to solve the above problems, a quantum dot composition according to an aspect of the present disclosure includes: a quantum dot; and an organic compound. At least a portion of the organic compound in the quantum dot composition is substituted with at least one metal compound selected from the group consisting of a metal-fluoro complex, a metal-fluoro complex containing a hydroxy group, and a metal oxide containing fluorine. Each of the metal compound and the quantum dot contains at least one metal element. A complex stability constant of the metal-fluoro complex of the at least one metal element contained in the metal compound in an aqueous solution is larger than a complex stability constant of the metal-fluoro complex of the at least one metal element contained in the quantum dot in the aqueous solution. The complex stability constant of the metal-fluoro complex of the at least one metal element contained in the metal compound in the aqueous solution is within a range of 0.1 or more and 20.0 or less.

In order to solve the above problems, a quantum-dot-composition-containing liquid according to an aspect of the present disclosure contains the quantum dot composition according to an aspect of the present disclosure.

In order to solve the above problems, a light-emitting element according to an aspect of the present disclosure contains the quantum dot composition according to an aspect of the present disclosure.

In order to solve the above problems, a light-emitting device according to an aspect of the present disclosure includes the light-emitting element according to an aspect of the present disclosure.

In order to solve the above problems, a method for producing a quantum dot composition according to an aspect of the present disclosure includes: a substituting step of substituting at least a portion of an organic compound with at least one metal compound selected from the group consisting of a metal-fluoro complex, a metal-fluoro complex containing a hydroxy group, and a metal oxide containing fluorine. The organic compound and a quantum dot are contained in an initial quantum dot composition. Each of the quantum dot and the metal compound to be used contains at least one metal element. A complex stability constant of the metal-fluoro complex of the at least one metal element contained in the metal compound in an aqueous solution is larger than a complex stability constant of the metal-fluoro complex of the at least one metal element contained in the quantum dot in the aqueous solution. The complex stability constant of the metal-fluoro complex of the at least one metal element contained in the metal compound in the aqueous solution is within a range of 0.1 or more and 20.0 or less.

### Advantageous Effects of Disclosure

An aspect of the present disclosure can provide a quantum dot composition that exhibits high stability to a OH group and excels in long-term reliability and light emission efficiency. The present disclosure can also provide a quantum-dot-composition-containing liquid, a light-emitting element, a light-emitting device, and a method for producing a quantum dot composition.

### BRIEF DESCRIPTION OF DRAWINGS

FIG. 1 is a partially enlarged view schematically illustrating a configuration of a light-emitting element according to a first embodiment.

FIG. 2 is a cross-sectional view schematically illustrating an example of a quantum dot according to the first embodiment.

FIG. 3 is a partially enlarged view schematically illustrating another example of the configuration of the light-emitting element according to a second embodiment.

FIG. 4 is a schematic diagram illustrating a reaction of a metal-fluoro complex and a hydroxide ion when water infiltrates into a light-emitting layer.

FIG. 5 is a cross-sectional view schematically illustrating an example of a quantum-dot-composition-containing liquid according to the first embodiment.

FIG. 6 is a flowchart schematically showing an example of a method for producing the light-emitting element according to the first embodiment.

FIG. 7 is a flowchart showing an example of a step of producing the quantum-dot-composition-containing liquid shown in FIG. 6.

FIG. 8 is a flowchart showing an example of a step of forming the light-emitting layer shown in FIG. 6.

FIG. 9 is a flowchart showing another example of the step of forming the light-emitting layer shown in FIG. 6.

FIG. 10 is a partially enlarged view schematically illustrating a configuration of the light-emitting element according to a second embodiment.

FIG. 11 is a flowchart showing an example of a step of forming the light-emitting layer in a method for producing the light-emitting element according to the first embodiment.

FIG. 12 schematically illustrates a process in which how a metal-fluoro complex forms a metal oxide shell on a surface of a quantum dot.

FIG. 13 is a cross-sectional view schematically illustrating an exemplary configuration of a main feature of a light-emitting device according to a third embodiment.

### DESCRIPTION OF EMBODIMENTS

### First Embodiment

### Configuration of Light-Emitting Element 1

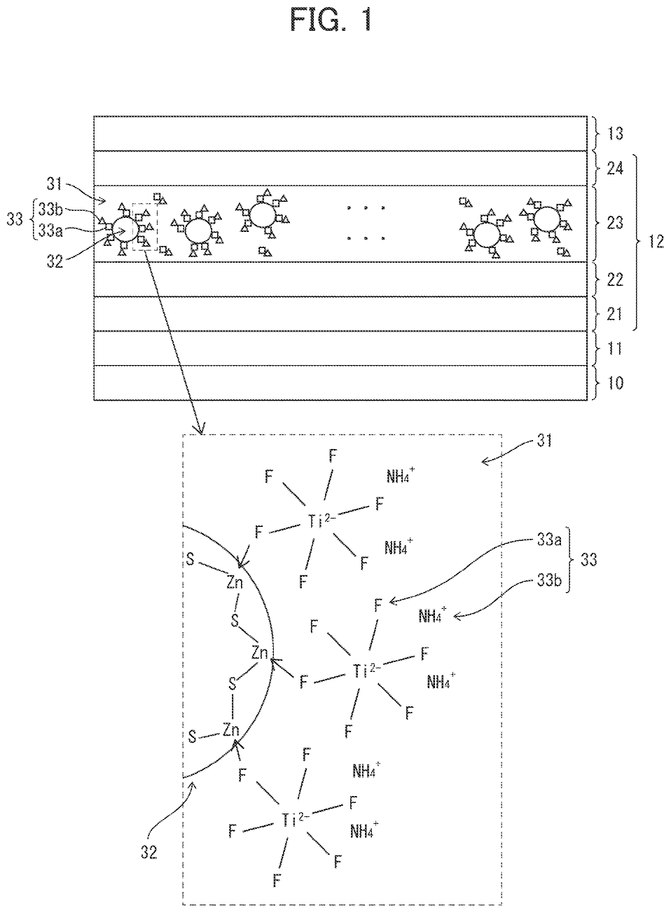

FIG. 1 is a partially enlarged view schematically illustrating a configuration of a light-emitting element 1 according to this embodiment.

As illustrated in FIG. 1, the light-emitting element 1 includes: an anode 11; a cathode 13; and a functional layer 12 provided between the anode 11 and the cathode 13, and including at least a light-emitting layer (hereinafter referred to as an “EML”) 23. Note that, in this embodiment, the layers between the anode 11 and the cathode 13 are collectively referred to as the functional layer 12.

The functional layer 12 may be either a single layer including the EML 23 alone, or a multilayer including another functional layer 12 except for the EML 23. Examples of the other functional layer 12 except for the EML 23 include: a hole injection layer (hereinafter referred to as “HIL”); a hole transport layer (hereinafter referred to as “HTL”); and an electron transport layer (hereinafter referred to as “ETL”).

Note that, in this embodiment, the term “below” means that a constituent feature is formed in a previous process before a comparative layer, and the term “above” means that a constituent feature is formed in a successive process after a comparative layer. In this embodiment, a direction from the anode 11 toward the cathode 13 in FIG. 1 is referred to as an upward direction, and a direction opposite the upward direction is referred to as a downward direction. Each of the layers from the anode 11 to the cathode 13 is typically supported by a substrate serving as a support. Hence, the light-emitting element 1 may include a substrate as the support.

The light-emitting element 1 illustrated in FIG. 1 includes, as an example, the substrate 10, the anode 11, the HIL 21, the HTL 22, the EML 23, the ETL 24, and the cathode 13, all of which are stacked on top of another in the stated order from below. The light-emitting element 1 includes the HIL 21, the HTL 22, the EML 23, and the ETL 24 collectively serving as the functional layer 12.

The substrate 10 is a support for forming each of the layers from the anode 11 to the cathode 13. The substrate 10 may be, for example, a glass substrate. Alternatively, the substrate 10 may be a flexible substrate such as a plastic substrate or a plastic film.

Furthermore, the light-emitting element 1 may be used as a light source of, for example, a light-emitting apparatus such as a display apparatus. If the light-emitting element 1 is a portion of a light-emitting apparatus, a substrate of the light-emitting apparatus is used as the substrate 10. Hence, the light-emitting element 1 may be referred to as the light-emitting element 1 with the substrate 10 included therein, or may be referred to as the light-emitting element 1 without the substrate 10. When the light-emitting element 1 is, for example, a portion of a display apparatus, the substrate 10 to be used may be, for example, an array substrate on which a plurality of thin-film transistors (TFTs) are formed.

The cathode 11 and the anode 13 are connected to a not-shown power source (e.g., a DC power source), so that a voltage is applied between the cathode 11 and the anode 13. Each of the anode 11 and the cathode 13 contains a conductive material, and the anode 11 and the cathode 13 are electrically and respectively connected to the HIL 21 and the ETL 24.

The anode 11 is an electrode that receives a voltage and supplies the holes to the EML 23. The cathode 13 is an electrode that receives a voltage and supplies the electrons to the EML 23.

At least one of the anode 11 or the cathode 13 is a light-transparent electrode. Note that either the anode 11 or the cathode 13 may be reflective to light; that is, a reflective electrode. The light-emitting element 1 can release light from toward a light-transparent electrode.

For example, if the light-emitting element 1 is a top-emission light-emitting element that emits light from toward the upper electrode, the upper electrode is a light-transparent electrode, and the lower electrode is a reflective electrode. Whereas, if the light-emitting element 1 is a bottom-emission light-emitting element that emits light from toward the lower electrode, the lower electrode is a light-transparent electrode, and the upper electrode is a reflective electrode.

The light-transparent electrode is formed of a conductive light-transparent material such as, for example, indium tin oxide (ITO), indium zinc oxide (IZO), silver nanowire (AgNW), a thin-film of a magnesium-silver (MgAg) alloy, or a thin-film of silver (Ag).

Whereas, the reflective electrode is formed of a conductive light-reflective material including a metal such as, for example, Ag, Al, or Cu, or including an alloy containing these metals. Note that a layer made of the light-transparent material and a layer made of the light-reflective material may be stacked on top of another to form the reflective electrode.

The HIL 21, which is capable of transporting the holes, promotes injection of the holes from the anode 11 into the HTL 22. The HIL 21 is made of a hole transporting material such as, for example, a composite (PEDOT: PSS) containing poly (3,4-ethylenedioxythiophene) (PEDOT) and polystyrene sulphonate (PSS).

The HTL 22, which is capable of transporting the holes, transports the holes from the HIL 21 to the EML 23. The HTL 22 is made of a hole transporting material such as, for example, poly[(9,9-dioctylfluorenyl-2,7-diyl)-co-(4,4′-(N-4-sec-butylphenyl))diphenylamine)] (TFB), poly[N,N′-bis(4-butylphenyl)-N,N′-bis(phenyl)-benzidine](p-TPD), polyvinylcarbazole (PVK), NiO, MoO₃, MgO, MgNiO, or LaNiO₃. These hole transporting materials may be used alone, or in combination of two or more as appropriate.

The ETL 24, which is capable of transporting the electrons, transports the electrons from the cathode 13 to the EML 23. The ETL 24 is made of an electron transporting material such as, for example, ZnO, MgZnO, TiO₂, Ta₂O₃, SrTiO₃, ZrO₂, or Ta₂O₅. These electron transporting materials may be used alone, or in combination of two or more as appropriate.

The EML23 is a QD light-emitting layer (a QD-composition-containing layer) including a QD composition 31 (a quantum dot composition) containing quantum dots (hereinafter referred to as “QDs”) 32 as a constituent element.

The QD composition 31 contains; a QD 32; and at least one metal compound 33 selected from the group consisting of a metal-fluoro complex (a metal-fluorine complex), a metal-fluoro complex containing a hydroxy group, and a metal oxide containing fluorine. Note that, hereinafter, the metal-fluoro complex containing a hydroxy group is referred to as a “hydroxy-group-containing metal-fluoro complex”. Furthermore, the metal oxide containing fluorine is referred to as a “fluorine-containing metal oxide”. Moreover, a compound containing a metal element is referred to as a “metal compound”.

In the EML 23, the holes transported from the anode 11 and the electrons transported from the cathode 13 recombine together, which forms an exciton. While the exciton transforms from a conduction band level to a valence band level of the QD 32, light is released.

The QD 32 is a dot having a maximum particle width of 100 nm or less. The QD is also referred to as a semiconductor nanoparticle because a typical composition of the QD is derived from a semiconductor material. Furthermore, the QD is also referred to as an inorganic nanoparticle because a typical composition of the QD is derived from an inorganic material. Moreover, the QD is also referred to as a nanocrystal because the QD has a specific crystal structure.

The QD 32 may have any given shape as long as the maximum width of the QD is within the above range. The shape of the QD shall not be limited to a three-dimensional spherical shape (a circular cross-section). For example, the QD 32 may have a polygonal cross-section, a bar-like three dimensional shape, a branch-like three dimensional shape, or a three dimensional shape having asperities on the surface. Alternatively, the QD 32 may have a combination of those shapes. The QD 32 contains at least one metal element. Examples of the metal element contained in the QD 32 include Cd, Zn, In, Sb, Al, Si, Ga, Pb, Ge, and Mg.

Specific examples of the material of the QD 32 include semiconductor materials such as CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe. These materials may be used alone or in combination of two or more as appropriate.

As can be seen, the QD 32 may be a semiconductor material containing at least one of the metal elements, or may be a semiconductor material containing a combination of at least one of the metal elements and a non-metal element such as S, Te, Se, N, P, or As.

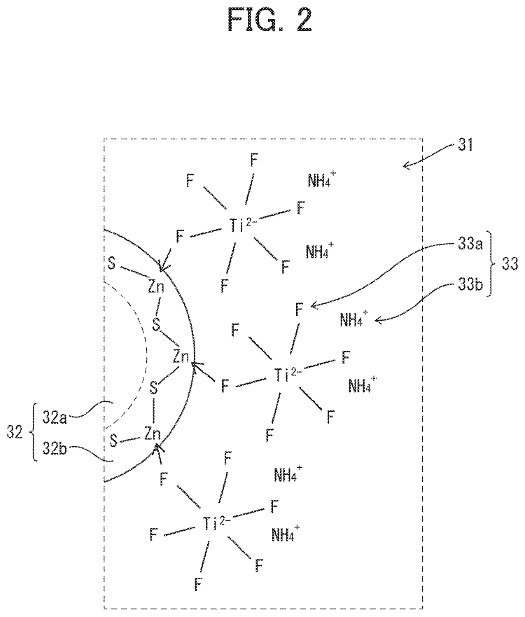

The QD 32 may be formed of a core alone. Alternatively, the QD 32 may be a binary-core QD, a tertiary-core QD, or a quaternary-core QD. Furthermore, as illustrated in FIG. 2, the QD 32 may be a core-shell QD including a core 32a and a shell 32b. Alternatively, the QD 32 may be either a core-shell QD or a core-multishell QD. Note that FIG. 2 is a cross-sectional view schematically illustrating an example of the QD 32. FIG. 2 schematically illustrates an exemplary configuration of a main feature of the QD composition 31. The QD 32 may contain a doped nanoparticle, or may have a composition-gradient structure. Furthermore, the shell 32b may be formed in the state of a solid solution and provided on a surface of the core 32a. In FIG. 2, a boundary between the core 32a and the shell 32b is indicated by a dotted line, which shows that it does not matter whether or not the boundary between the core 32a and the shell 32b is identified by analysis. The shell 32b may include a plurality of layers.

As described above, the QD 32 contains the core 32a and the shell 32b having at least one layer. Thanks to such a feature, light emission efficiency is increased by a quantum confinement effect. Furthermore, when a hydroxide ion (OH⁻) infiltrates into the QD composition 31 because of infiltration of an object such as water, the feature can reduce a decrease in light emission efficiency caused when OH, which serves as a hydroxy group (a OH group), directly bonds to the surface of the core 32a.

Note that, as described above, the QD 32 may contain at least one metal element. However, from viewpoints of, for example, light emission efficiency, emission half-width, and ease of availability, the core 32a preferably contains at least one of, for example, Cdₓ₁Zn₁₋ₓ₁ Se_{y1}S_{1-y1} (0≤x1≤1, 0≤y1≤1) or Inₓ₂Ga₁₋ₓ₂P (0≤x2≤1).

Furthermore, the shell 32b preferably contains at least one of metal oxides such as, for example, Cdₓ₃Zn₁₋ₓ₃Se_{y3}S_{1-y3} (0≤x3≤1, 0≤y3≤1) or MOₓ₄ (0<x4≤3 wherein M represents a metal element).

The metal element represented by M and used for the shell 32b shall not be limited to a particular metal element as long as the metal element satisfies the condition of 0<x4≤3 as described above. Examples of the metal element include Al, Ti, Sn, V, Ni, Si, and Ga. Specific examples of the metal oxide used for the shell 32b include Al₂O₃, TiO₂, SnO₂, V₂O₃, NiO, SiO₂, and GaO.

As can be seen, the shell 32b has a larger band gap than the core 32a. Thanks to such a feature, light emission efficiency is increased by a quantum confinement effect. Simultaneously, when OH-infiltrates into the QD composition 31, the feature can reduce a decrease in light emission efficiency caused when OH directly bonds to the surface of the shell 32b.

If the QD 32 has a core-shell structure, examples of the material of the QD 32 (i.e., a combination of the materials of the core 32a and the shell 32b) include ZnSe—ZnS, InP—ZnS, and CdSe—CdS.

Furthermore, the QD 32 may be a Cd-free chalcopyrite-based QD represented by ABX2. Here, A and B represent metal atoms of a cationic species with different valences. Examples of the cationic species include silver (Ag), aluminum (Al), indium (In), gallium (Ga), copper (Cu), zinc (Zn), silicon (Si), germanium (Ge), and tin (Sn). X represents either a non-metal atom or a semi-metal atom of an anionic species, such as sulfur(S), selenium (Se), tellurium (Te), phosphorus (P), or arsenic (As).

When the core 32a is formed of such a chalcopyrite-based material, examples of the material of the shell 32b may include ZnS, ZnSe, GaO, and GaS. Alternatively, the material may be a combination of such substances.

Note that if the QD 32 contains the shell 32b, the shell 32b may be provided to the surface of the core 32a. The shell 32b preferably covers the entire core 32a; however, the shell 32b does not have to completely cover the core 32a. The shell 32b may be partially formed on the surface of the core 32a. The QD 32 is determined to have a core-shell structure when a cross-section of the QD 32 is observed and shows that either the shell 32b is partially formed on the surface of the core 32a or the shell 32b coats the core 32a. Hence, the shell 32b is sufficiently determined to cover the whole core 32a when a cross-section of the QD 32 is observed. Note that the cross-section can be observed with, for example, a scanning transmission electron microscope (STEM) or a transmission electron microscope (TEM).

An emission wavelength of the QD 32 can be changed in various manners depending on, for example, the size and the composition of the particle. The QD 32 emits visible light. A particle size and a composition of the QD 32 are appropriately adjusted so that an emission wavelength of the QD 32 can be controlled from a blue wavelength region to a red wavelength region.

Hence, the QD 32 may be, for example, a blue QD that emits a blue light, a green QD that emits a green light, or a red QD that emits a red light.

Note that, the blue light has a peak emission wavelength in a wavelength band of, for example, 400 nm or more and 500 nm or less. Furthermore, the green light has a peak emission wavelength in a wavelength band of, for example, more than 500 nm and 600 nm or less. Moreover, the red light has a peak emission wavelength in a wavelength band of more than 600 nm and 780 nm or less.

In the QD composition 31, the surface of the QD 32 has at least one metal compound 33 selected from the group consisting of a metal-fluoro complex, a hydroxy-group-containing metal-fluoro complex, and a fluorine-containing metal oxide.

The metal compound 33 contains at least one metal element. As to the metal compound 33 used in this embodiment, a complex stability constant of the metal-fluoro complex of the at least one metal element contained in the metal compound 33 in an aqueous solution is larger than a complex stability constant of the metal-fluoro complex of the at least one metal element contained in the QD 32 in the aqueous solution.

A tendency of OH substitution of a metal-fluoro complex in an aqueous solution is indicated by the complex stability constant. Wherein K (log β) represents the complex stability constant of the metal-fluoro complex in an aqueous solution, the complex stability constant K is indicated by an equilibrium constant of a reaction formula (A) below as shown in Expression (1) below.

$$M + mF ⇔ {MF}_{m} . \qquad ( A )$$

$$K ( Log β ) = [ {MF}_{m} ] / ( [ M ] \times {[ F ]}^{m} ) . \qquad ( 1 )$$

Wherein, in Expression (1), [MF] represents an activity (a concentration) of the metal-fluoro complex (MF) in the aqueous solution. Furthermore, [M] represents an activity (a concentration) of a metal (M) in equilibrium with a metal (M) of the metal-fluoro complex (MF), and [F] represents an activity (a concentration) of fluorine (F) in equilibrium with fluorine (F) of the metal-fluoro complex (MF).

Wherein K1 is a complex stability constant of the metal-fluoro complex of the at least one metal element contained in the metal compound 33 used in the present disclosure in an aqueous solution at 25° C., the complex stability constant K1 is within a range of 0.1 or more and 20.0 or less.

Note that, as described above, if the QD 32 contains a plurality of metal elements, it is desirable that the complex stability constant of the metal-fluoro complex of the metal element contained in the largest amount in the metal compound 33 among at least one metal element contained in the metal compound 33 in the aqueous solution is larger than the complex stability constant of the metal-fluoro complex of the metal element contained in the largest amount in the QD 32 in the aqueous solution.

In particular, if the QD 32 contains a plurality of metal elements in the surface (an outermost layer) of the QD 32, it is desirable that the complex stability constant of the metal-fluoro complex of the metal element contained in the largest amount in the metal compound 33 among at least one metal element contained in the metal compound 33 in the aqueous solution is larger than the complex stability constant of the metal-fluoro complex of the metal element contained in the largest amount in the surface (the outermost layer) of the QD 32 in the aqueous solution.

Here, the surface (the outermost layer) of the QD 32 is: the shell 32b if the QD 32 includes the shell 32b; and the surface of the core 32a if the QD 32 is formed of the core 32a alone without including the shell 32b.

Furthermore, the statement “the metal element contained in the largest amount in the metal compound 33 among at least one metal element contained in the metal compound 33” means that, if the metal compound 33 contains one metal element alone, the metal element is the one metal element contained in the metal compound 33, and that, if the metal compound 33 contains a plurality of metal elements, the metal element is a metal element: included in the plurality of metal elements in the metal compound 33; and contained in the largest amount in the metal compound 33.

Moreover, the metal element contained in the largest amount in either the metal compound 33 or the QD 32 is a metal element determined to have the highest concentration when a cross-section of either the metal compound 33 or the QD 32 is observed. In addition, the metal element contained in the largest amount in the surface (the outermost layer) of the QD 32 is a metal element determined to have the highest concentration near the surface of the QD 32 when a cross-section of the QD 32 is observed.

Note that if the metal compound 33 contains a plurality of metal elements, it is desirable that the complex stability constant K1 of the metal-fluoro complex of the metal element contained in the largest amount in the metal compound 33 in an aqueous solution at 25° C. is within a range of 0.1 or more and 20.0 or less.

Table 1 shows an example of complex stability constants K of various metal ions and metal-fluoro complexes having the metal ions as central metal ions in an aqueous solution at 25° C. Note that a typically disclosed equilibrium constant (a complex stability constant) of a metal ion in an aqueous solution is a value measured at 25° C. Hence, the commonly disclosed value of the equilibrium constant (the complex stability constant) of a metal ion in the aqueous solution can be directly adopted as the complex stability constant K. Note that the typically disclosed equilibrium constant (the complex stability constant) varies slightly, depending on measurement conditions such as the activity (the concentration) of each metal ion. Hence, Table 1 shows the highest values (i.e., the values in the most stable state) ever checked among typically disclosed constant equilibrium constants (complex stability constants). Furthermore, an activity (a concentration) of each metal ion is a complex stability constant indicating a smaller value ever checked among 0, 0.5, and 1.0, as a smaller value of interaction between the complexes.

TABLE 1

| Metal Ion | Complex Stability Constant |
|---|---|
| Sr²⁺ | 0.1 |
| Co²⁺ | 0.4 |
| Ni²⁺ | 0.5 |
| Ca²⁺ | 0.58 |
| Mn²⁺ | 0.7 |
| Fe²⁺ | 0.8 |
| Cd²⁺ | 0.85 |
| Cu²⁺ | 0.9 |
| Zn²⁺ | 1.15 |
| Mg²⁺ | 1.32 |
| Bi³⁺ | 1.42 |
| Pb²⁺ | 2.55 |
| Si⁴⁺ | 3.0 |
| Ti⁴⁺ | 4.0 |
| Mn³⁺ | 5.65 |
| V⁵⁺ | 7.0 |
| V³⁺ | 8.1 |
| Ge⁴⁺ | 8.94 |
| Sn²⁺ | 9.5 |
| Cr³⁺ | 10.2 |
| Ga³⁺ | 10.5 |
| Sb³⁺ | 10.9 |
| In³⁺ | 11.5 |
| Fe³⁺ | 11.9 |
| Y³⁺ | 12.1 |
| Al³⁺ | 19.8 |
| B³⁺ | 21.6 |
| Zr⁴⁺ | 28.3 |
| Hf⁴⁺ | 38.0 |

Note that Table 1 omits a complex stability constant K of P among Zn, B, and P contained in the fluoride-containing ligand described in Patent Document 1. However, it is understood that no F⁻ desorbs from [PF₆]⁻ in the aqueous solution, and the complex stability constant K of P is far greater than 20.0.

As described above, examples of the metal ions that satisfy 0.1≤K1≤20.0 include metal ions in Table 1 such as Sr²⁺, Co²⁺, Ni²⁺, Ca²⁺, Mn²⁺, Mn³⁺, Fe²⁺, Fe³⁺, Cd²⁺, Cu²⁺, Zn²⁺, Mg²⁺, Bi³⁺, Pb²⁺, Si⁴⁺, Ti⁴⁺, V³⁺, V⁵⁺, Ge⁴⁺, Sn²⁺, Cr³⁺, Ga³⁺, Sb³⁺, In³⁺, Y³⁺, and Al³⁺.

Hence, the metal compound 33 may be, for example, at least one metal compound: selected from the group consisting of a metal-fluoro complex, a hydroxy-group-containing metal-fluoro complex, and a fluorine-containing metal oxide; and having at least one metal element selected from the group consisting of Sr, Co, Ni, Ca, Mn, Fe, Cd, Cu, Zn, Mg, Bi, Pb, Si, Ti, V, Ge, Sn, Cr, Ga, Sb, In, Y, and Al.

More specifically, the metal compound 33 contains, for example, at least one metal compound: selected from the group consisting of a metal-fluoro complex, a hydroxy-group-containing metal-fluoro complex, and a fluorine-containing metal oxide; and containing, as a center metal (a center metal ion), any one metal element selected from the group consisting of Sr (II), Co (II), Ni (II), Ca (II), Mn (II), Mn (III), Fe (II), Fe (III), Cd (II), Cu (II), Zn (II), Mg (II), Bi (III), Pb (II), Si (IV), Ti (IV), V (III), V (V), Ge (IV), Sn (II), Cr (III), Ga (III), Sb (III), In (III), Y (III), and Al (III).

Note that the complex stability constant K1 is within a range of preferably 1.2 or more and 19.0 or less. As described above, examples of the metal ions that satisfy 1.2≤K1≤19.0 include metal ions in Table 1 such as Mg²⁺, Bi³⁺, Pb²⁺, Si⁴⁺, Ti⁴⁺, Mn³⁺, V³⁺, V⁵⁺, Ge⁴⁺, Sn²⁺, Cr³⁺, Ga³⁺, Sb³⁺, In³⁺, Fe³⁺, Y³⁺, and Al³⁺.

Hence, the metal compound 33 is preferably, for example, at least one metal compound: selected from the group consisting of a metal-fluoro complex, a hydroxy-group-containing metal-fluoro complex, and a fluorine-containing metal oxide; and containing, as a center metal (a center metal ion), any one metal element selected from the group consisting of Mg (II), Bi (III), Pb (II), Si (IV), Ti (IV), Mn (III), V (III), V (V), Ge (IV), Sn (II), Cr (III), Ga (III), Sb (III), In (III), Fe (III), Y (III), and Al (III).

Furthermore, when the complex stability constant K of the metal-fluoro complex of the at least one metal element contained in the QD 32 is K2, the complex stability constant K1 described above is preferably larger by 0.1 or more than the complex stability constant K2. For example, if Zn is contained in the surface (the outermost layer) of the QD 32, examples of the metals, whose complex stability constant K1 satisfies 0.1≤K1≤20.0 and K1≥(K2+0.1), include Mg (II), Bi (III), Pb (II), Si (IV), Ti (IV), Mn (III), V (III), V (V), Ge (IV), Sn (II), Cr (III), Ga (III), Sb (III), In (III), Fe (III), Y (III), and Al (III), as Table 1 shows.

Moreover, the complex stability constant K1 is preferably larger by 1.5 or more than the complex stability constant K2. For example, if Zn is contained in the surface (the outermost layer) of the QD 32, examples of the metals, whose complex stability constant K1 satisfies 0.1≤K1≤20.0 and K1≥(K2+1.5), include Si (IV), Ti (IV), Mn (III), V (III), V (V), Ge (IV), Sn (II), Cr (III), Ga (III), Sb (III), In (III), Fe (III), Y (III), and Al (III), as Table 1 shows.

In addition, the complex stability constant K1 is preferably larger by 2.5 or more than the complex stability constant K2. For example, if Zn is contained in the surface (the outermost layer) of the QD 32, examples of the metals, whose complex stability constant K1 satisfies 0.1≤K1≤20.0 and K1≥(K2+2.5), include Ti (IV), Mn (III), V (III), V (V), Ge (IV), Sn (II), Cr (III), Ga (III), Sb (III), In (III), Fe (III), Y (III), and Al (III), as Table 1 shows.

Described below in this embodiment will be a case where the metal compound 33 is a ligand containing a metal-fluoro complex and the QD 32 contains a Zn atom.

For example, if the QD 32, with either the core 32a alone or a core-shell structure, has a Zn atom on the surface of the QD 32, the Zn atom exposed on the surface could be a cause for deactivation of an exciton. In order to reduce a decrease in light emission efficiency because of Zn exposed on the surface of the QD 32 (i.e., on the surface of either the core 32a or the shell 32b), the surface of the QD 32 is desirably coordinated with a ligand.

In order to stably disperse the QDs 32 in the solvent, the QDs 32 have to be separated from one another. In such a case, the ligands have to have a certain length. On the other hand, as to a carrier-injection light-emitting element, shorter ligands are more desirable. However, the halogen has a small ionic radius, and when the halogen is used alone, the QDs 32 agglomerate, but do not disperse.

Hence, in this embodiment, a metal-fluoro complex is used as a ligand. The metal-fluoro complex is larger in ionic radius than a halogen ion alone. Hence, according to this embodiment, even if the metal-fluoro complex is used alone as the ligand as illustrated in FIG. 1, the QD 32 can be kept from agglomerating and dispersed. In addition, the metal-fluoro complex serves as a ligand shorter than a typically used organic ligand for the QDs to stably disperse, thereby successfully bring the QDs 32 close to one another. Thanks to such a feature, compared with an organic ligand, the metal-fluoro complex can increase carrier injection properties, and reduce a decrease in light emission efficiency because of a defective surface of the QD 32.

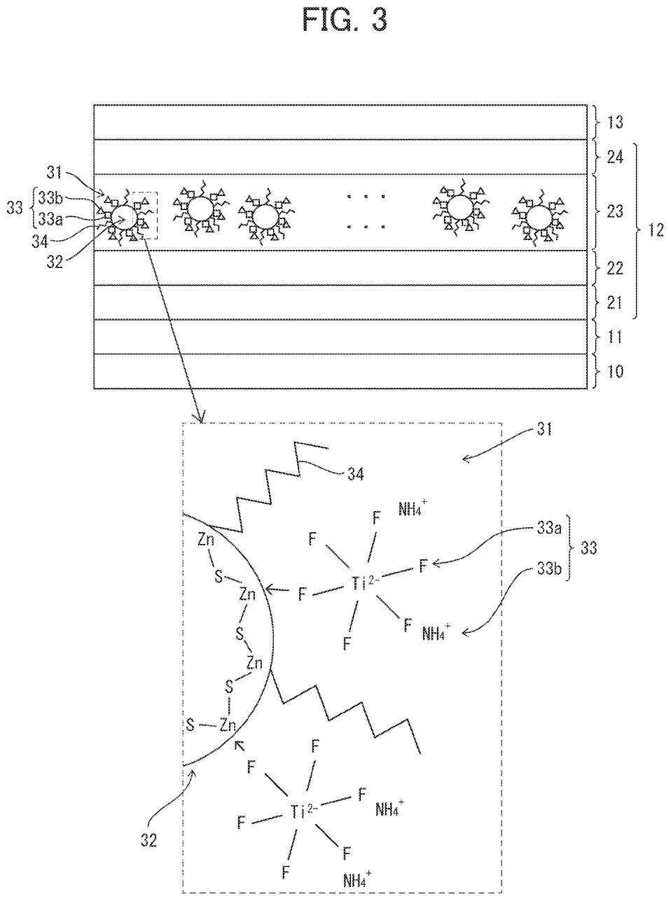

Note that, in order to stably disperse the QDs 32, as illustrated in FIG. 3, the QD composition 31 may contain an organic compound 34 that serves as an organic ligand. FIG. 3 is a partially enlarged view schematically illustrating another example of the configuration of the light-emitting element 1 according to this embodiment.

When the QD composition 31 contains the organic compound 34, the organic compound 34 may be a known organic compound of various kinds. The organic compound 34 contains at least one coordinating functional group used as an organic ligand and capable of coordinating to the QD 32.

Typical examples of the coordinating functional group include at least one functional group selected from the group consisting of an amino (—NR₂) group, a phosphonic (—P(═O)(OR)₂) group, a phosphine (—PR₂) group, a phosphine oxide (—P(═O)R₂) group, a carboxyl (—C(═O)OH) group, and a thiol (—SH) group.

Note that among the above coordinating functional groups, the thiol group is more likely to coordinate to a QD; in particular, to a QD containing Zn, than the other coordinating functional groups. Hence, the thiol group can coordinate to a QD more stably.

Examples of the organic compound 34 to be used as the organic ligand include: amine-based compounds such as oleylamine and dodecylamine; phosphonic-acid-based compounds such as (12-phosphonododecyl) phosphonic acid and 11-mercaptoundecylphosphonic acid; phosphine-based compounds such as trioctylphosphine and tributylphosphine; phosphine-oxide-based compounds such as trioctylphosphine oxide and tributylphosphine oxide; aliphatic-based compounds such as oleic acid and octanoic acid; and thiol-based compounds such as dodecanethiol and octanethiol.

Note that, in order to facilitate carrier injection, a proportion of the organic compound 34 contained in the QD composition 31 is desirably low, or the QD composition 31 does not desirably contain the organic compound 34. In the QD composition, a proportion of the metal compound 33 to the total amount of the metal compound 33 and the organic compound 34 is desirably 40% or more, more desirably 70% or more, and particularly desirably 90% or more.

Synthetic or commercially-available QDs are often coordinated with organic ligands as initial ligands. Commercially available QDs are typically provided in the form of a QD-composition-containing liquid containing organic ligands. The organic ligands are used as a dispersant to improve dispersibility of the QDs in the QD-composition-containing liquid. The organic ligands are also used to improve surface stability and storage stability of the QDs. In addition, the QDs are synthesized by, for example, a wet technique. The organic ligands are coordinated to a surface of the QDs to control a particle size of the QDs. Hence, the QD-composition-containing liquid synthesized by the wet technique contains the organic ligands used for the synthesis of the QDs.

Thus, in order to obtain the QD composition 31, the organic ligand, contained in a synthetic or commercially-available QD-composition-containing liquid and serving as the initial ligand, has to be substituted with the metal compound 33. Note that, hereinafter, the synthetic or commercially-available liquid containing QD composition is referred to as an “initial QD-composition-containing liquid”.

The organic compound 34 may be an organic compound serving as an organic ligand (an initial ligand) contained in the synthetic or commercially-available initial QD-composition-containing liquid. Alternatively, the organic compound 34 may be an organic compound other than the initial ligand.

The EML23 is formed by application of the QD-composition-containing liquid containing the QD composition 31. As an example, in this embodiment, the QD-composition-containing liquid is produced through a ligand substitution process in a solution state. Note that the QD-composition-containing liquid and the ligand substitution will be described later.

As illustrated in FIGS. 1 and 3, in the EML 23, at least some of the plurality of metal compounds 33 coordinate to the QD 32. The metal-fluoro complex is anionic and negatively charged. Thus, as a ligand, the metal-fluoro complex is attracted to the positively charged surface of the QD 32. Hence, the metal-fluoro complex can coordinate to the QD 32.

Note that, in this embodiment, the statement “to coordinate” means that the ligand and the surface of the QD 32 interact with each other. For example, the term indicates that the ligand is adsorbed onto the surface of the QD 32 (i.e., the ligand modifies the surface of (surface-modifies) the QD 32). Note that, here, the statement “adsorbed” means that the concentration of the ligands is higher on the surface of the QD 32 than in the surroundings of the surface. The adsorption may be chemisorption representing a chemical bond between the QD 32 and the ligand. Alternatively, the adsorption may be either physisorption, or electrostatic adsorption.

Hence, as long as the ligand can interact with the surface of the QD 32, the ligand may bond to the QD 32 through coordinate bonding, covalent bonding, ionic bonding, or hydrogen bonding. Alternately, the ligand and the QD 32 do not have to bond together. Examples of the interaction include coordinate bonding interaction, common bonding interaction, ionic bonding interaction, and hydrogen bonding interaction. Alternatively, the interaction is either van der Waals interaction or another molecular interaction.

As can be seen, in this embodiment, the statement “ligand” refers to a molecule or an ion coordinatable to the surface of the QD 32. Any of the metal compounds 33 described as an example is a molecule capable of interacting with the surface of the QD 32. As described above, the metal compounds 33 can be used as ligands. Furthermore, in this embodiment, the statement “ligand” collectively refers not only to a molecule or an ion coordinated to the surface of the QD 32 but also to a molecule or an ion that can be coordinated but is not coordinated.

A type of ligands contained in the EML 23 can be identified with a combination of a plurality of analysis techniques such as the MALDI-TOF-MS, the LC-MS/MS, the TOF-SIMS, the ICP-AES, and the NMR.

The MALDI (i.e., the matrix-assisted laser desorption ionization) is a technique to emit a nitrogen laser beam (having a wavelength of 337 nm) to a matrix mixture, and to rapidly heat (for several nanoseconds), and vaporize, the matrix mixture from the outermost surface to a depth of 100 nm.

The TOF-MS (i.e., the time-of-flight mass spectrometry) is a technique to analyze mass, taking advantage of a fact that the flight time of ions differs depending on a difference in a mass to charge ratio; namely, an m/z value.

The LC-MS/MS (i.e., the liquid chromatography mass spectrometry) is a technique to identify molecules with an apparatus including a combination of a high-performance liquid chromatograph (HPLC) and a triple quadrupole mass spectrometer (MS/MS). The LC-MS/MS excels in the identification of molecules because the connected mass spectrometers can obtain a more separated mass spectrum than the LC-MS.

The TOF-SIMS (i.e., the time-of-flight secondary ion mass spectrometry) involves emitting a primary ion beam to a sample under ultrahigh vacuum, so that an extreme surface (i.e., 1 to 3 nm) of the sample releases secondary ions. When the secondary ions are introduced into a time-of-flight (TOF) mass spectrometer, a mass spectrum of the outermost surface of the sample is obtained. Here, when the amount of primary ions to be emitted is reduced, the surface component can be detected either as molecular ions with the chemical structure maintained or as partially cleaving fragments. Such a feature makes it possible to obtain information on an elemental composition and a chemical structure of the outermost surface.

The ICP-AES (i.e., the inductively coupled plasma atomic emission spectrometry) is a technique to introduce an atomized liquid sample into a plasma and disperse, with a spectrograph, emitted light observed in the plasma for each element, in order to qualitatively and quantitatively analyze the element. This technique is mainly used for analysis of metal elements.

The NMR (i.e., the nuclear magnetic resonance) is a technique to emit an electromagnetic wave from outside to a nucleus with a magnetic field applied thereto, and observe a resonance phenomenon of the nuclear spin, in order to analyze a molecule structure of a compound.

Likewise, the metal element contained in a QD 32 can be identified by the above-described techniques. If the QD 32 is a core QD, metal elements detected from the QD 32 (i.e., the core 32a) are determined as metal elements contained in the QD 32. Here, the metal element detected in largest amount is desirably determined as the metal element contained in the QD 32. Whereas, if the QD 32 is a core-shell QD and the core 32a and the shell 32b can be detected separately, a metal element detected from the shell 32b is determined as the metal element contained in the QD 32. If the core 32a and the shell 32b cannot be separated from each other, the core 32a and the shell 32b are assumed to contain a common metal element. Hence, the metal element detected from the entire QD 32 is determined as the metal element contained in the QD 32. In any case, the metal element detected in largest amount is desirably determined as the metal element contained in the QD 32.

Note that, as described above, the metal-fluoro complex is an anion, and examples of a counterion include cations such as H⁺, NH⁴⁺, Na⁺, K⁺, and R₄N⁺. Here, R for the RAN is, for example, CH₃CₓH₂ₓ. X is preferably an integer of 1 to 3, because, for example, the integer is easily available.

Hence, the metal compound 33 contains: an anion 33a; and a cation 33b, and the anion 33a contains a metal-fluoro complex. The metal-fluoro complex and the counterion may bond together in the EML 23 to form a metal-fluoro complex compound. The metal-fluoro complex compound to be used preferably exhibits high solubility in a polar solvent; that is, in particular, in an amphoteric solvent made of polar molecules such as ethanol. Hence, the counterion is preferably one of the cations described above as an example, and the cation 33b is preferably at least one selected from the group consisting of the cations described above as an example.

As described above, the QD composition 31 contains: the QD 32; and at least one metal compound 33. If the QD composition 31 contains: the QD 32; and the metal compound 33 (e.g., a metal-fluoro complex compound) serving as a ligand coordinated to the QD 32, the QD composition 31 contains, as illustrated in FIG. 1, for example, the QD 32, and the metal compound 33 either not yet coordinated to the QD 32 or coordinated to the QD 32. Here, the state “not yet coordinated” is a state in which the anion 33a and the cation 33b bond together. Furthermore, the state “coordinated” is a state in which the anion 33a, which is, for example, a metal-fluoro complex compound interacts with the surface of the QD 32 (e.g., a state in which the metal-fluoro complex compound bonds to the surface of the QD 32).

Likewise, if the QD composition 31 further contains the organic compound 34 serving as an organic ligand and coordinated to the QD 32, the QD composition 31 contains the organic compound 34 either not yet coordinated to the QD 32 or coordinated to the QD 32. Note that if the organic compound 34 has, for example, a thiol (—SH) group serving as a coordinating functional group, the thiol group releases a hydrogen atom, and the organic compound 34 coordinates to the QD 32 through bonding with a sulfide (—S—). Here, the organic compound 34 “not yet coordinated” is the organic compound 34 in which a hydrogen atom, which is to be released by coordination, bonds.

In FIG. 1, shown as an example is a case where the metal compound 33 is titanium ammonium fluoride containing: a titanium-fluoro complex ([TiF⁶]²⁻) serving as the anion 33a and containing titanium (IV) as a central metal (a central metal ion); and NH⁴⁺ serving as the cation 33b. Note that the metal-fluoro complex compound according to this embodiment shall not be limited to such an example. The metal-fluoro complex compound can be any metal-fluoro complex compound in various kinds formed in a combination of a metal-fluoro complex containing a metal element described above as an example and a counter ion described above as an example. Note that, hereinafter, the complex [TiF₆]²⁻ is simply denoted as [TiF₆]²⁻. Other complexes are also denoted in the same manner.

In this embodiment, the metal-fluoro complex is used as a ligand. Such a feature can reduce agglomeration of the QDs 32 as described above, and increase carrier injection properties. In addition, when OH⁻ infiltrates into the QD composition 31, which causes reduction in light emission efficiency of the QD 32, the fluoride ion (F⁻) in the metal-fluoro complex is substituted with the OH⁻. Such a feature can keep an OH group from directly bonding to the surface of the QD 32.

Stability of the metal-fluoro complex to the OH group (i.e., reactivity indicating to what extent F⁻ in the metal-fluoro complex is substituted with OH⁻) varies, depending on a kind of the metal element in the metal-fluoro complex. The stability (reactivity) can be compared, using the complex stability constant K described above.

In a metal-fluoro complex having a small complex stability constant K, F⁻ is easily substituted with OH in the metal-fluoro complex. Moreover, there are many metal species that become metal hydroxides as the final products. For example, Zn(OH)₂ found near the QD 32 would cause the QD 32 to be deactivated and quenched. As a result, quantum efficiency decreases together with electrical conductivity, thereby reducing carrier injection properties. In addition, in view of long-term stability, it is not preferable to use a metal-fluoro complex that is likely to form a hydroxide. Hence, preferably used is a metal-fluoro complex having a high complex stability constant. Furthermore, as described above, the metal element contained in the metal compound 33 is selected so that the complex stability constant K1 of the metal-fluoro complex of at least one metal element contained in the metal compound 33 in an aqueous solution is larger than the complex stability constant K2 of the metal-fluoro complex of at least one metal element contained in the QD 32 in an aqueous solution.

Taking TiF₆²⁻ as an example, TiF₆²⁻ is higher in complex stability constant K than ZnF₄²⁻, and successfully serves as a more stable complex ligand to an OH group.

As shown in an expression below, ZnF₄²⁻ releases the ligand with water (OH).

Zn—F+OH⁻→Zn—OH+F⁻.

If the complex stability constant K is 20.0 or less, Fis substituted with OH as described above. In particular, Zn has a relatively low complex stability constant K, and the reaction to Zn—OH is likely to proceed. Hence, if the metal compound 33 is ZnF₄²⁻, the metal compound 33 is likely to become a metal hydroxide as a final product. Note that the more unstable metal element the complex contains, the more likely the complex contains OH from the beginning.

As described above, if the metal compound 33 is ZnF₄²⁻ when the QD 32 contains Zn as a metal element, the metal element contained in the metal compound 33 is the same as the metal element contained in the QD 32, and the complex stability constant K1 is equal to the complex stability constant K2. Hence, as described above, the ligand directly coordinated to the QD 32 is released with water (OH), and metal hydroxide is formed on the surface of the QD 32. As a result, the QD 32 is quenched, showing a deterioration in characteristics.

Whereas, as to, for example, [AlF₆]³⁻ having stable Al—F boding, F⁻ in an excessively stable metal-fluoro complex is hardly substituted with OH⁻. Hence, if such a metal-fluoro complex is used as a ligand, OH infiltrated into the EML 23 directly bonds to Zn²⁺ on the surface of the QD 32. Thus, it is not preferable to use, as a ligand, a highly stable metal-fluoro complex having a complex stability constant K of more than 20.0.

In contrast, as described above, regarding the metal-fluoro complex used in this embodiment as a ligand, the complex stability constant K1 is larger than the complex stability constant K2, and the complex stability constant K1 is within a range of 0.1 or more and 20.0 or less.

In this case, the complex stability constant K1 is 20.0 or less. Thus, when OH⁻ infiltrates into the EML 23, the OH⁻ is substituted with F⁻. Whereas, the complex stability constant K1 is 0.1 or more. Thus, the metal-fluoro complex does not originally contain OH⁻.

Furthermore, the complex stability constant K1 is larger than the complex stability constant K2. Thus, in response to the infiltration of OH into the EML 23, F⁻ not directly coordinated to the surface of the QD 32 (i.e., F⁻ other than F⁻ on the surface of the QD 32) is substituted with OH⁻. Hence, according to this embodiment, the ligand directly coordinated to the surface of the QD 32 is not released, and an OH group does not directly bond to the surface of the QD 32. Therefore, the QD 32 can be kept from being quenched.

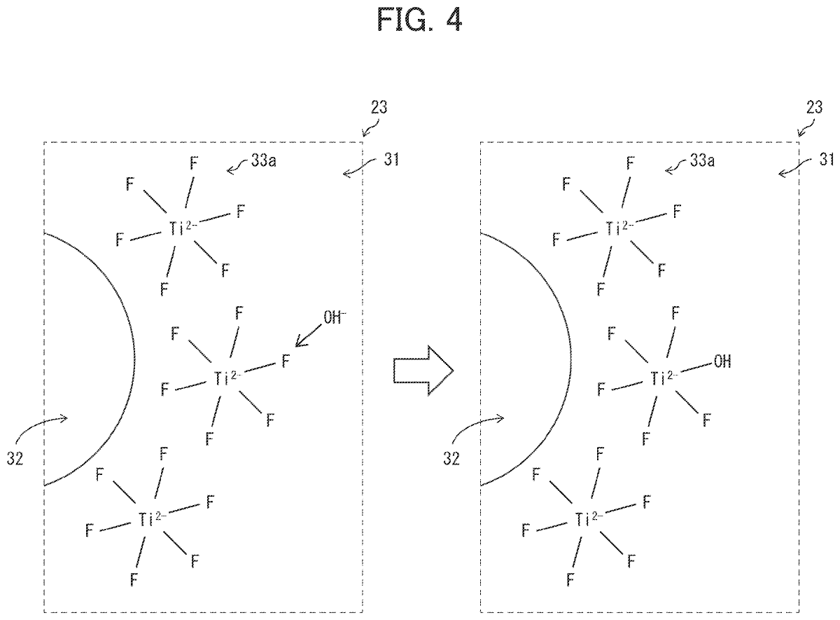

FIG. 4 is a schematic diagram illustrating a reaction of a metal-fluoro complex and a OH when water infiltrates into the EML 23.

As illustrated in FIG. 4, when OH⁻ infiltrates into the QD composition 31 because, for example, water infiltrates into the EML 23, F⁻ in the metal-fluoro complex is substituted with OH⁻. As a result, the metal-fluoro complex bonds to the OH group instead of the metal, such as a Zn atom, included in the QD 32 (e.g., the metal included in the surface (the outermost layer) of the QD 32). As can be seen, according to this embodiment, the ligand functions as a sacrificial layer for OH⁻, and successfully keeps the OH group from bonding directly to the metal, such as a Zn atom, included in the QD 32. As a result, the disclosure can reduce degradation of the QD 32 per se, and reduce a decrease in light emission efficiency of the QD 32.

Note that, as described above, when OH⁻ infiltrates into the QD composition 31, F⁻ in the metal-fluoro complex is partially substituted with OH⁻. Hence, the QD composition 31 may contain a metal-fluoro complex containing a hydroxy group. In other words, at least some of the metal-fluoro complexes contained in the QD composition 31 may have some of fluoride ions replaced with hydroxide ions.

Furthermore, if a halogen ligand is a monoatomic halide ion such as, for example, F⁻, the halogen ligand has a ligand diameter twice an ionic radius of the halide ion. A complex ion radius of TiF₆²⁻ is, for example, twice or more than an ionic radius of a single F (i.e., F⁻). For example, F has a ligand diameter of 130 pm; whereas, TiF₆²⁻ has a ligand diameter of approximately 300 pm. Hence, if, for example, TiF₆²⁻ is used as the ligand, the distance between the QDs 32 can be increased as compared with a case where F is used. Such a feature allows the QDs 32 to disperse more stably. Thus, this embodiment can provide a quantum dot composition that exhibits high stability to a OH group and excels in long-term reliability and light emission efficiency. This embodiment can also provide the light-emitting element 1 including the EML 23 containing the quantum dot composition.

Note that, FIGS. 1 and 3 illustrate an exemplary case where the light-emitting element 1 has a known structure in which the anode 11 is a lower electrode. However, the light-emitting element 1 may have an inverted structure in which the cathode 13 is a lower electrode. The inverted structure may include, for example, the cathode 13, the ETL 24, the EML 23, the HTL 22, the HIL 21, and the anode 11, all of which are stacked on top of another from below in the stated order above the substrate 10.

As described before, the EML23 is formed by application of the QD-composition-containing liquid containing the QD composition 31.

### QD-Composition-Containing Liquid 41

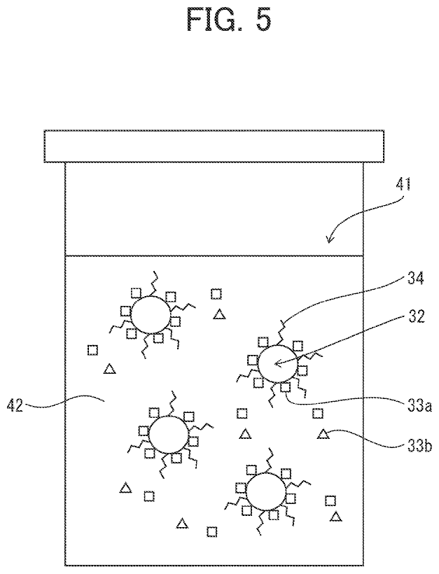

FIG. 5 is a cross-sectional view schematically illustrating an example of a QD-composition-containing liquid 41 according to this embodiment.

The QD-composition-containing liquid 41 according to this embodiment contains the QD composition 31 and a solvent 42.

As described above, the QD composition 31 contains: the QD 32; and the metal compound 33. The metal compound 33 contains, as described before, the anion 33a and the cation 33b, and the anion 33a contains a metal-fluoro complex. As illustrated in FIG. 4, in the QD-composition-containing liquid 41, the metal-fluoro complex compound serves as the anion 33a and the cation 33b.

FIG. 5 exemplifies a case where the QD composition 31 contains the organic compound 34 (i.e., a residual organic ligand). Note that this embodiment shall not be limited to such an example. As described before, the QD composition 31 may contain the QD 32 and the metal compound 33.

The QD-composition-containing liquid 41 is a dispersion liquid in which the QD composition 31 is dispersed in the solvent 42. Note that the QD-composition-containing liquid 41 may be a colloidal solution in which, for example, the QD composition 31 is colloidally dispersed in the solvent 42.

The solvent 42 is selected in accordance with a ratio of the metal-fluoro complex, which is contained in the QD composition 31 and coordinated to the surface of the QD 32, to the organic compound 34. For example, if the metal-fluoro complex, which is readily soluble in a polar solvent, is larger in proportion, the polar solvent is selected. If the organic compound 34 is larger in proportion, a nonpolar solvent is selected. Note that, it is more desirable as the substitution of the organic compound 34 with the metal-fluoro complex proceeds further. Hence, the polar solvent is suitable as the solvent 42. The polar solvent is suitably a polar solvent in the form of a liquid at room temperature. The polar solvent is a solvent other than water. Examples of the solvent 42 include, more preferably, amphoteric solvents such as methanol and ethanol. Note that solvent 42 shall not be limited to such examples. The solvent 42 may be, for example, a non-aqueous polar solvent such as dimethyl sulfoxide (DMSO).

The metal-fluoro complex is desirably contained in excessive amount so that ligand concentration of the QD-composition-containing liquid 41 is set to maintain intervals between the QDs 32 and to protect the surface of the QDs 32. Note that a content of the metal-fluoro complex with respect to the QDs 32 may be any given content as long as the QDs 32 can be uniformly dispersed in the solvent 42.

### Method for Producing Light-Emitting Element 1.

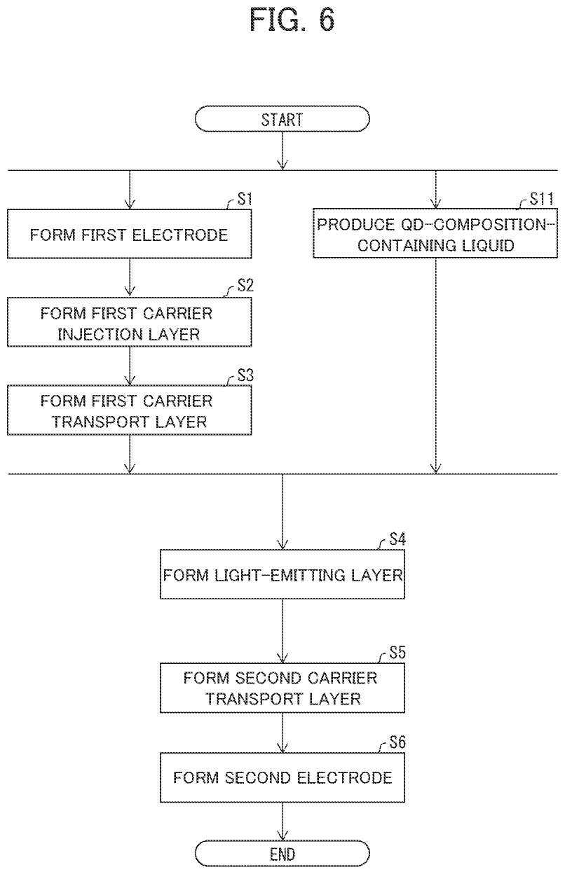

Described next will be an example of a method for producing the light-emitting element 1 according to the first embodiment. FIG. 6 is a flowchart schematically showing an example of a method for producing the light-emitting element 1 according to this embodiment. In the description below, for convenience of description, for example, the anode 11 is a first electrode, the cathode 13 is a second electrode, a first electrode forming step is an anode forming step, and a second electrode forming step is a cathode forming step. Hence, in the description below, the HTL 22 is a first carrier transport layer, and the ETL 24 is a second carrier transport layer. However, the anode 11 and the cathode 13 may be formed and stacked in any given order. For example, the cathode 13 may be the first electrode, the anode 11 may be the second electrode, the ETL 24 may be the first carrier transport layer, and the HTL 22 may be the second carrier transport layer. Thus, the first electrode forming step may be the cathode forming step, the second electrode forming step may be the anode forming step, a first carrier transport layer forming step may be an electron transport layer forming step, and a second carrier transport layer forming step may be a hole transport layer forming step. When the cathode 13 is the first electrode and a first carrier injection layer is the HIL 21, a first carrier injection layer forming step succeeds the electron transport layer forming step. Furthermore, when the cathode 13 is the first electrode and the light-emitting element 1 includes an electron injection layer, the first carrier injection layer forming step may be an electron injection layer forming step.

As illustrated in FIG. 6, in the method for producing the light-emitting element 1 according to this embodiment, first, for example, the anode 11 is formed above the substrate 10 to serve as the first electrode (Step S1: the first electrode forming step, the anode forming step). Next, the HIL 21 is formed (Step S2: the first carrier injection layer forming step, the hole injection layer forming step). Next, the HTL 22 is formed (Step S3, the first carrier transport layer forming step, the hole transport layer forming step). Simultaneously, the QD-composition-containing liquid 41 is produced (i.e., prepared) (Step S11, a QD-composition-containing liquid producing step). As described before, the QD-composition-containing liquid 41 contains: the QD composition 31 including the QD 32 and the metal compound 33; and the solvent 42.

Then, the EML 23 is formed of the QD-composition-containing liquid 41 (Step S4, the light-emitting layer forming step). Next, the ETL 24 is formed (Step S5, the second carrier transport layer forming step, the electron transport layer forming step). Next, the cathode 13 is formed (Step S6: the second electrode forming step, the cathode forming step). This is how the light-emitting element 1 is produced.

Note that if the light-emitting element 1 is a portion of a display apparatus, at Step S4, a red light-emitting layer containing red QDs, a green light-emitting layer containing green QDs, and a blue light-emitting layer containing blue QDs are selectively applied by a process similar to a known process such as photolithography.

Furthermore, after Step S1 and before Step S2, an edge cover forming step may be carried out as necessary to form an edge cover covering an edge of the lower electrode (i.e., the anode 11 in this embodiment).

The anode 11 at Step S1 and the cathode 13 at Step S6 are formed by a technique such as, for example, evaporation or sputtering.

The HIL 21 at Step S2 and the HTL 22 at Step S3 are formed by a technique such as, for example, coating, sputtering, or sol-gel process. The ETL 24 at Step S5 is formed by, for example, coating.

The QD-composition-containing liquid producing step (Step S11) includes a ligand substituting step in a liquid (Step S21).

As described before, a synthetic or commercially-available initial QD-composition-containing liquid contains organic ligands serving as initial ligands. At least some of the initial ligands are coordinated to QDs.

Hence, at Step S11 (i.e., the QD-composition-containing liquid producing step), an initial ligand coordinated to the QD 32 has to be substituted with a metal-fluoro complex. Thus, the Step S11 (i.e., the QD-composition-containing liquid producing step) includes the ligand substituting step (Step S21) at which the synthesized or commercially available initial ligand (an organic ligand), which is contained in the initial QD-composition-containing liquid, is substituted with the metal-fluoro complex (the metal compound 33).

In this embodiment, the QD-composition-containing liquid 41 is produced through a ligand substitution process in a solution state.

Described below will be a method for substituting the initial ligand (i.e., the organic ligand), which is coordinated to QD 32, with the metal-fluoro complex.

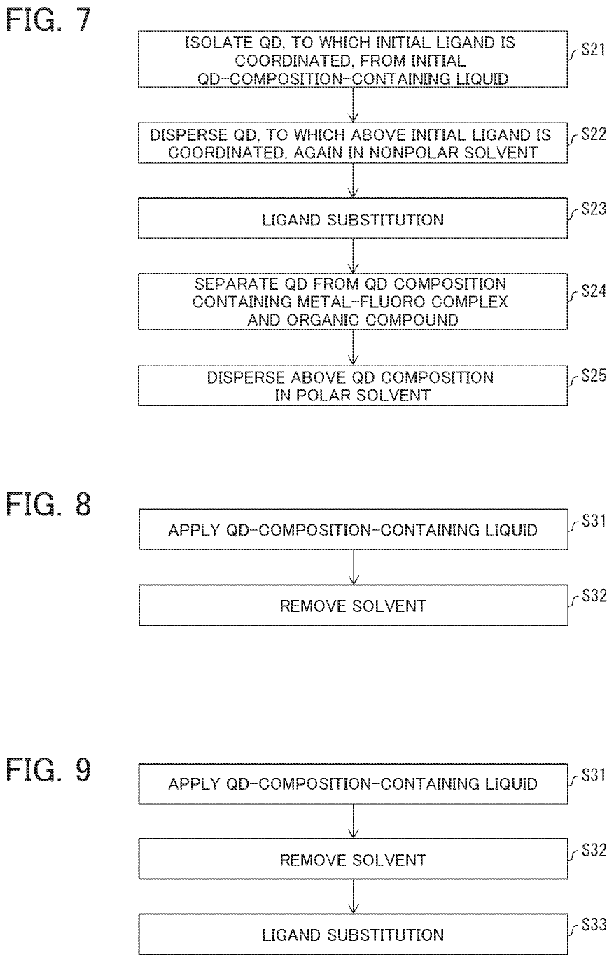

FIG. 7 is a flowchart showing an example of the step of producing the QD-composition-containing liquid shown in FIG. 6.

Note that exemplified below is a case where the initial ligand is the organic compound 34, and where the organic compound 34, which is contained in the synthetic or commercially-available initial QD-composition-containing liquid, is substituted with a metal-fluoro complex.

At the ligand substituting step, first, the QD 32 is isolated from the initial QD-composition-containing liquid (Step S21, an isolation step). The QD 32 has a surface to which the organic compound 34 is coordinated.

At Step S21, first, the initial QD-composition-containing liquid is collected into a reaction vessel such as a centrifuge tube. The initial QD-composition-containing liquid contains: an initial QD composition containing the QD 32 and the organic compound 34; and a solvent. The solvent is a nonpolar solvent.

Next, an excess amount of poor solvent is delivered in a form of droplets into the initial QD-composition-containing liquid in the reaction vessel, in order to cause precipitation of the QDs 32 contained in the initial QD-composition-containing liquid and coordinated with the organic compound 34. The poor solvent is a solvent such as ethanol in which the QDs 32 are not dispersed. Next, the liquid in the reaction vessel undergoes centrifugal separation so that the supernatant fluid is removed.

Next, the precipitated QDs 32 (i.e., the QDs 32 to which the organic compound 34 is coordinated) are rinsed and isolated. Note that the rinse of the QDs 32 involves an operation including: adding another nonpolar solvent to the precipitated QDs 32; causing the QDs 32 to disperse again; and after that, adding another poor solvent and performing centrifugal separation to remove the supernatant fluid. Such an operation is repeated multiple times. This operation can remove excessive organic ligands contained in the initial QD-composition-containing liquid and not coordinated to the QDs 32.

Next, another nonpolar solvent serving as a solvent is added to the QDs 32 isolated at Step S21 and contained in the reaction vessel. The QDs 32 are dispersed again in the solvent (i.e., the nonpolar solvent) (Step S22, a redispersion step). Thus, a QD-composition-containing liquid is obtained to contain the QDs 32, the organic compound 34 coordinated to the QDs 32, and the solvent (i.e., the nonpolar solvent).

Next, a small amount of metal-fluoro complex compound solution is added to, and stirred together with, the QD-composition-containing liquid contained in the reaction vessel. The metal-fluoro complex compound solution is formed of a polar solvent (e.g., ethanol) into which a metal-fluoro complex compound is dissolved. The metal-fluoro complex compound solution serves as a ligand solution containing the metal compound 33 as ligands and a solvent. After that, the reaction liquid in the reaction vessel is left to stand for a predetermined time period. Thus, a ligand exchange reaction is performed so that at least a portion of the organic compound 34 contained in the initial QD composition is substituted with the metal-fluoro complex (i.e., substituted with the ligands) that is a kind of the metal compound 33 (Step S23, the ligand substituting step).

Note that conditions for the ligand substitution may be any given conditions including a concentration of the metal-fluoro complex compound in the metal-fluoro complex solution, the amount of the metal-fluoro complex solution to be added, and a time period required for the stirring and standing. These conditions may be appropriately set according to, for example, the materials to be used, so that a proportion of the metal compound 33 to the total amount of the organic compound 34 and the metal compound 33 in the obtained QD composition 31 is determined to be a desired proportion.

Next, an excess amount of the poor solvent is delivered in a form of droplets again into the reaction vessel. After that, the liquid in the reaction vessel undergoes centrifugal separation so that the supernatant fluid is removed. Thus, the excess metal-fluoro complex contained in the supernatant fluid and not coordinated to the QDs 32 is removed together with the solvent, and the QDs 32 are separated from the QD composition 31 containing the metal-fluoro complex and the organic compound 34 that are found on the surface of the QDs 32 (Step S24, a QD composition separating step).

After that, a polar solvent serving as the solvent 42 is added into the reaction vessel, and the QD composition 31 is dispersed in the polar solvent (Step S25, a QD composition dispersing step). As a result, the QD-composition-containing liquid 41 is successfully obtained to contain the QD composition 31 and the solvent 42.

FIG. 8 is a flowchart showing an example of Step S4 (i.e., the light-emitting layer forming step).

At Step S4, first, the QD-composition-containing liquid 41 is applied to the HTL 22 to form a coating film of the QD-composition-containing liquid 41 (Step S31, a QD-composition-containing liquid applying step). Note that the coating film can be formed by any given technique appropriately selected from such techniques as bar-coating, spin coating, and inkjet printing. Next, the coating film is heated and dried, and the solvent 42 is removed (Step S32, a solvent removing step). This step can form, for example, the EML 23 containing the QD composition 31 as illustrated in FIG. 3.

FIG. 9 is a flowchart showing another example of Step S4 (the light-emitting layer forming step).

As described before, in order to facilitate carrier injection, a proportion of the organic compound 34 contained in the QD composition 31 is desirably low, or the QD composition 31 does not desirably contain the organic compound 34. Hence, if the QD-composition-containing liquid 41 contains the organic compound 34, as illustrated in FIG. 9, the solvent may be removed at Step S32, and a thin film containing the QD composition 31 may be formed. After that, additional ligands may be substituted (Step S33 a ligand substituting step).

The ligand substitution in the thin film can be carried out, for example, as follows. First, the metal-fluoro complex compound solution serving as a ligand solution is supplied to the thin film by, for example, spin coating. The metal-fluoro complex compound solution is formed of a polar solvent (e.g., ethanol) into which a metal-fluoro complex compound is dissolved. Note that, instead of supplying the metal-fluoro complex compound solution by, for example, spin coating, a substrate provided with the thin film is immersed into a metal-fluoro complex compound solution. Next, if necessary, the organic compound 34 and the excess metal-fluoro complex compound not coordinated to the QD 32 are rinsed with a rinse agent and removed. After that, the thin film is heated and dried, and the solvent is removed.

As can be seen, after the thin film is formed, an additional ligand substituting process is carried out to increase the amount of substituted ligands. The ligand substituting step can form, for example, the EML 23 illustrated in FIG. 1.

Note that the above example is just an example. At Step S11 (the QD-composition-containing liquid producing step), the ligand substitution condition is appropriately adjusted so that the EML 23 in FIG. 1 is successfully formed. Alternatively, the initial QD-composition-containing liquid is applied to form the thin film, and, after that, the thin film is supplied with the metal-fluoro complex compound solution, so that the ligand substitution is performed. That is, at least a portion of the organic compound 34 contained in the initial QD-composition-containing liquid is subjected to the ligand substitution. After that, the solvent is removed at, for example, Step S24 (the QD composition separating step) or Step S32 (the solvent removing step) so that the QD composition according to this embodiment may be formed. Furthermore, the QD composition according to this embodiment can be produced by the ligand substitution of the organic compound 34 included in the initial QD composition not containing a solvent. For example, as described above, the initial QD composition may be formed into a shape of a thin film, and after that, the ligand substitution may be performed, in order to produce the QD composition according to this embodiment.

### Second Embodiment

Another embodiment of present disclosure will be described below. Note that, for convenience in description, like reference signs designate members having identical functions between this embodiment and the above embodiment. These members will not be elaborated upon repeatedly. This embodiment describes a difference from the first embodiment.

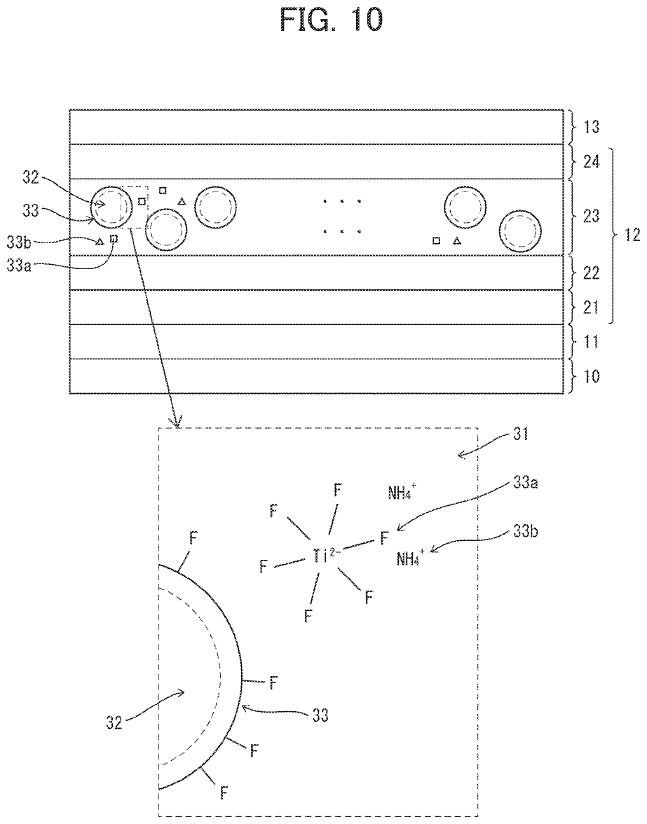

FIG. 10 is a partially enlarged view schematically illustrating a configuration of a light-emitting element 1 according to this embodiment.

As illustrated in FIG. 10, the QD composition 31 according to this embodiment contains the metal compound 33 containing a fluorine-containing metal oxide. Note that FIG. 10 exemplifies a case where the QD composition 31 contains: a metal oxide containing fluorine; and a metal-fluoro complex.

For example, as with Zn(OH)₂ generated of ZnF₄²⁻, metal hydroxide generated when F⁻ of a metal-fluoro complex is substituted with OH⁻ causes a decrease in quantum efficiency and carrier injection properties because of deactivation of the QDs 32 as described in the first embodiment.

As described in the first embodiment, a tendency of OH substitution of the metal-fluoro complex in an aqueous solution is indicated a complex stability constant. A metal element having a larger complex stability constant K is more stable when bonding to F⁻, and F⁻ is less likely to be substituted with OH⁻. A metal element having a smaller complex stability constant K is more unstable when bonding to F⁻, and F⁻ is more likely to be substituted with OH⁻.

Most metal species form metal hydroxide. When F⁻ is substituted with OH⁻ in the metal-fluoro complex, the metal-fluoro complex coordinated to the surface of the QDs 32 changes to a hydroxy (hydroxide) complex.

However, depending on the metal species, the hydroxy complex and the metal hydroxide produced by the dehydration reaction of the hydroxy complex are unstable. Hence, when some metal-fluoro complexes are substituted with OH⁻ by the hydrolysis reaction, the dehydration reaction further proceeds. Thus, the metal-fluoro complexes form metal oxides.

For example, when Ti, Sn, V, and Si are substituted with OH⁻, Ti, Sn, V, and Si undergo a dehydration reaction and respectively form TiO₂, SnO₂, V₂O₃, and SiO₂.

Such a reaction is more likely to occur when the reaction field is an inhomogeneous field at the QD/solution interface than when the reaction field is a homogeneous field in the solution, and a metal oxide is deposited preferentially on the surface of the QDs 32. Thus, the reaction produces a shell of the metal oxide that covers the surface of each QD 32. Note that, as a feature of the metal oxide produced by the hydrolysis reaction and the dehydration reaction of the metal-fluoro complex, the metal oxide contains fluorine. That is, in the metal oxide produced by the hydrolysis reaction and by the dehydration reaction of the metal-fluoro complex, fluoride ions remain.

Such a shell of the metal oxide protects the QD 32 against infiltration of excess OH⁻. Hence, the metal-fluoro complex desirably contains a metal element that forms a metal oxide by hydrolysis. Such a feature makes it possible to form a metal oxide on the surface of the QD 32 (e.g., on the surface of the shell 32b), and to protect the QD 32 against the infiltration of excess OH⁻.

Note that, in order to form a metal hydroxide and a hydroxy complex that is a precursor of the metal oxide, the complex stability constant K has to be 20.0 or less, as described before. As described before, when the complex stability constant K exceeds 20.0, the substitution with OH itself is less likely to occur. For example, metal-fluoro complexes such as B, P, and Al are stable as complexes, and form neither metal hydroxides nor metal oxides.

Among the metal elements capable of forming a hydroxy complex, for example, Ti, Sn, V, and Si produce unstable hydroxy complexes and form metal oxides by a dehydration reaction.

Furthermore, the deposited metal oxide is preferably a material that does not block injection of the carriers in the light-emitting element 1. Among the above elements, Ti, Sn, and V are more preferable than Si having a large bandgap.

Hence, the metal element contained in the metal compound 33 is preferably at least one selected from the group consisting of Ti, Sn, V, and Si, and, more preferably, at least one selected from the group consisting of Ti, Sn, and V.

Thus, the metal-fluoro complex preferably contains at least one selected from the group consisting of TiF₆²⁻, SnF₆²⁻, VF₆⁻, and SiF₆²⁻. Furthermore, the metal oxide formed on the surface of the QDs 32 excels at carrier conductivity. Hence, the metal-fluoro complex preferably contains at least one selected from the group consisting of TiF₆²⁻, SnF₆²⁻, and VF₆⁻.

TiO₂, SnO₂, or V₂O₃, formed of a metal-fluoro complex containing Ti, Sn, or V, exhibits high electron or hole conductivity. For example, TiO₂ formed of TiF₆²⁻ is an n-type semiconductor, and has conductivity. Hence, in the light-emitting element 1, carriers are effectively injected.

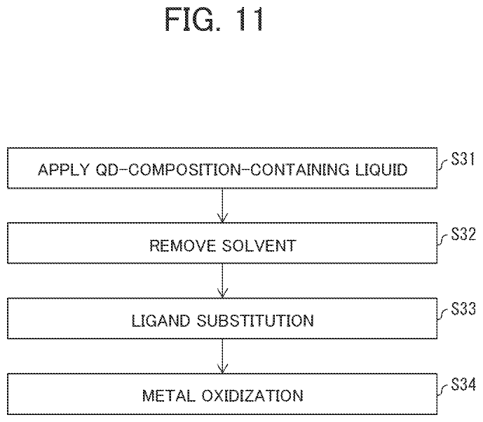

FIG. 11 is a flowchart showing an example of a step of forming the light-emitting layer (Step S4) in a method for producing the light-emitting element 1 according to this embodiment. In the method for producing the light-emitting element 1 according to this embodiment, at Step S4, for example, after either Step S32 or Step S33, the metal-fluoro complex is oxidized to form a metal oxide (Step S34, a metal oxidizing step). Note that, FIG. 11 exemplifies a case where Step S33 precedes Step S34. Otherwise, the method for producing the light-emitting element 1 according to this embodiment is the same as that of the light-emitting element 1 according to the first embodiment.

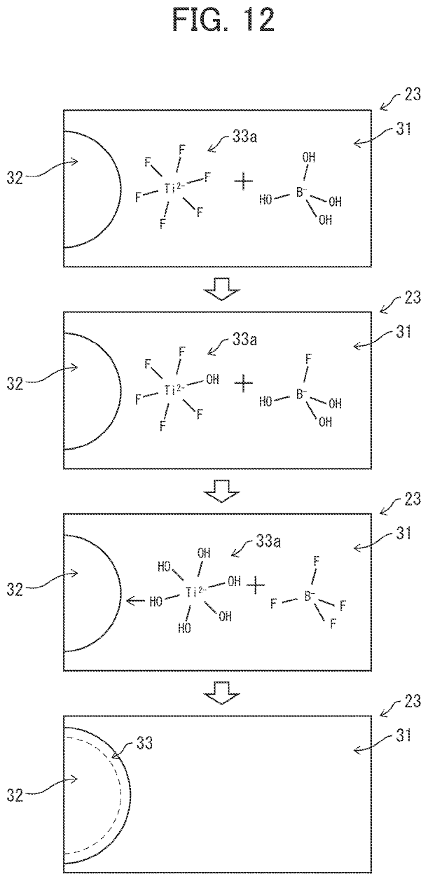

Described below will be a method for oxidizing a metal-fluoro complex to form a metal oxide at Step S34, with reference to FIG. 12.

FIG. 12 schematically illustrates a process in which how a metal-fluoro complex forms a shell formed of a metal oxide (hereinafter referred to as a “metal oxide shell”) on a surface of a QD 32. Note that FIG. 12 illustrates only the anion 33a of the metal compound 33, and omits illustrations of, for example, the cation 33b and fluoride ions contained in the metal oxide shell to be finally formed.

At Step S34, first, a substrate, provided with the thin film obtained either at Step S33 or at Step S32 and containing the QD composition 31, is immersed in, for example, a boric acid solution. Hence, the metal-fluoro complex is hydrolyzed. Note that FIG. 12 exemplifies a case where the metal-fluoro complex is TiF₆²⁻.

The QD 32 in the QD composition 31 has a surface coordinated with an unstable metal-fluoro complex lower in complex stability constant K than boron (K). When the boric acid solution is added to the QD composition 31, as illustrated in FIG. 12, F⁻ is gradually substituted with OH⁻. As a result, the metal-fluoro complex (TiF₆²⁻) coordinated to the surface of the QD 32 becomes a hydroxy complex (Ti(OH)₆²⁻), and B(OH)₄⁻ becomes BF₄⁻.

However, because Ti(OH)₆²⁻ is unstable, Ti(OH)₆²⁻ is finally deposited in the form of a metal oxide solid by a dehydration reaction. Here, as described before, the reaction is more likely to occur when the reaction field is an inhomogeneous field at the QD/solution interface than when the reaction field is a homogeneous field in the solution, and the metal oxide is deposited preferentially on the surface of the QD 32. As a result, a metal compound shell, made of the metal compound 33 containing the metal oxide containing fluorine, is formed to cover the front of the QD 32. Note that the metal oxide shell may be formed in the state of a solid solution and provided on the surface of the QD 32. In FIGS. 10 and 12, a boundary between the QD 32 and the metal compound shell is indicated by a dotted line, which shows that it does not matter whether or not the boundary between the QD 32 and the metal compound shell is identified by analysis.

### Third Embodiment

### Application to Display Apparatus

As described above, the light-emitting element 1 according to the first and second embodiments may be used as a light source of, for example, a light-emitting device such as a display apparatus. This embodiment exemplifies a case where a light-emitting device according to this embodiment is a display apparatus.

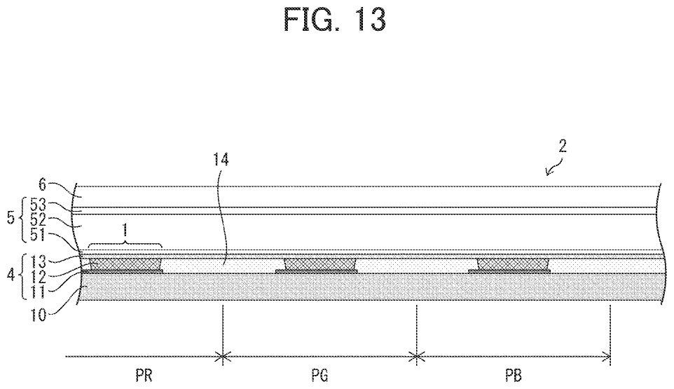

FIG. 13 is a cross-sectional view schematically illustrating an exemplary configuration of a main feature of a display apparatus 2 (a light-emitting device) according to this embodiment.

The display apparatus 2 has a plurality of pixels. Each of the pixels is provided with the light-emitting element 1. The display apparatus 2 includes, as the substrate 10, an array substrate in which, for example, a TFT layer is formed. The display apparatus 2 further includes: a light-emitting element layer 4 including a plurality of the light-emitting elements 1 having different emission wavelengths; a sealing layer 5; and a functional film 6, all of which are stacked on top of another in the stated order above the substrate 10.

The display apparatus 2 illustrated in FIG. 13 includes, as pixels: a red pixel PR that emits a red light; a green pixel PG that emits a green light; and a blue pixel PB that emits a blue light. Between the pixels, an edge cover 14 is provided to cover an edge of a lower electrode (e.g., the anode 11 in FIG. 13) and to function as a pixel separating film for separating the neighboring pixels from one another. The edge cover 14 is insulative.

In forming the edge cover 14, for example, an organic material such as polyimide or acrylic resin is applied. After that, the applied organic material is patterned by photolithography to form the edge cover 14.

The display apparatus 2 includes, as the plurality of light-emitting elements 1 having different emission wavelengths, a red light-emitting element that emits a red light, a green light-emitting element that emits a green light, and a blue light-emitting element that emits a blue light. The red pixel PR is provided with the red light-emitting element serving as a light-emitting element 1. The green pixel PG is provided with the green light-emitting element serving as a light-emitting element 1. The blue pixel PB is provided with the blue light-emitting element serving as a light-emitting element 1.

The red light-emitting element includes a red EML serving as the EML 23. The red EML contains red QDs serving as the QDs 32 and emitting a red light. The green light-emitting element includes a green EML serving as the EML 23. The green EML contains green QDs serving as the QDs 32 and emitting a green light. The blue light-emitting element includes a blue EML serving as the EML 23. The blue EML contains blue QDs serving as the QDs 32 and emitting a blue light. The same light-emitting elements 1 (the same pixels) include the same kind of QDs 32. The light-emitting element layer 4 includes the plurality of light-emitting elements 1 provided for the respective pixels. Above the substrate 10, the layers of each of the light-emitting elements 1 are stacked on top of another.

The substrate 10 is an array substrate provided with, for example, a TFT layer serving as a drive element layer. The TFT layer is provided with a pixel circuit including such a drive element as a TFT. The pixel circuit drives the light-emitting element 1.

The light-emitting element layer 4 includes, for example: a plurality of the anodes 11; the cathode 13; the functional layer 12 provided between the anodes 11 and the cathode 13; and the edge cover 14 insulative and covering an edge of each of the anodes 11, all of which form the light-emitting elements 1. Each of the anodes 11, which functions as a so-called pixel electrode (an island-shaped lower electrode), is shaped into an island and provided on the substrate 10 for a corresponding one of the light-emitting elements 1 (i.e., the pixels). The cathode 13 is provided above the lower electrode across the functional layer 12 and the edge cover 14. The cathode 13, which functions as a common electrode (a common upper electrode), is provided in common to all the light-emitting elements 1 (i.e., all the pixels). The light-emitting elements 1 function as light sources to cause the pixels to emit light. The light-emitting elements 1 may have the configuration described either in the first embodiment or in the second embodiment.

The light-emitting element layer 4 is covered with the sealing layer 5. The sealing layer 5 is transparent to light, and includes, for example, a first inorganic sealing film 51, an organic sealing film 52, and a second inorganic sealing film 53 in the stated order from below (i.e., from toward the light-emitting element layer 4). Note that the configuration of the sealing layer 5 shall not be limited to such a configuration. The sealing layer 5 may be formed of an inorganic sealing film alone, or may be a multilayer stack including five layers or more of such films as an organic sealing film and an inorganic sealing film. Furthermore, the sealing layer 5 may be, for example, a sealing glass. The sealing layer 5 seals the light-emitting elements 1, thereby making it possible to prevent water and oxygen from penetrating into the light-emitting elements 1.

Each of the first inorganic sealing film 51 and the second inorganic sealing film 53 can be formed of a silicon oxide film, a silicon nitride film, a silicon oxynitride film, or a multilayer film including these films. These films can be formed by, for example, chemical vapor deposition (CVD). The organic sealing film 52 is a light-transparent organic film thicker than the first inorganic sealing film 51 and the second inorganic sealing film 53. The organic sealing film 52 can be formed of an applicable photosensitive resin such as polyimide resin and acrylic resin.

Note that, as illustrated in FIG. 13, the display apparatus 2 may include the functional film 6 provided on the sealing layer 5 and having at least one of, for example, an optical compensation function, a touch sensor function, and a protection function.

As described above, the display apparatus 2 illustrated in FIG. 13 includes the light-emitting elements 1 according to the first embodiment or the second embodiment, as the light-emitting elements 1 having different emission wavelengths. Hence, the display apparatus 2 includes a QD composition containing layer containing the QD composition 31 and serving as the EML 23. Thus, this embodiment can achieve the same advantageous effects described in the first embodiment or the second embodiment. Hence, this embodiment can provide a light-emitting device that exhibits high stability to a OH group and excels in long-term reliability and light emission efficiency.

Note that FIG. 13 exemplifies a case where the light-emitting device is a display apparatus. However, this embodiment shall not be limited to such a case. The light-emitting device simply has to include the light-emitting elements 1 described in the first embodiment or the second embodiment. Furthermore, the light-emitting device simply has to include a QD composition containing layer containing the QD composition 31 described in the first embodiment or the second embodiment.

For example, the QD composition containing layer may be a wavelength conversion layer formed of a wavelength conversion member, and the light-emitting device may be a wavelength conversion member. Moreover, the display apparatus may include the wavelength conversion member as a photoelectric converting unit.

In any case, according to this embodiment, the light-emitting device includes a QD composition containing layer containing the QD composition 31. Hence, this embodiment can provide the light-emitting device that exhibits high stability to a OH group and excels in long-term reliability and light emission efficiency.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A quantum dot composition, comprising:
a quantum dot; and at least one metal compound selected from the group consisting of a metal-fluoro complex, a metal-fluoro complex containing a hydroxy group, and a metal oxide containing fluorine,
wherein each of the metal compound and the quantum dot contains at least one metal element,
a complex stability constant of the metal-fluoro complex of the at least one metal element contained in the metal compound in an aqueous solution is larger than a complex stability constant of the metal-fluoro complex of the at least one metal element contained in the quantum dot in the aqueous solution, and
the complex stability constant of the metal-fluoro complex of the at least one metal element contained in the metal compound in the aqueous solution is within a range of 0.1 or more and 20.0 or less.

2. A quantum dot composition, comprising:
a quantum dot; and an organic compound, at least a portion of the organic compound in the quantum dot composition being substituted with at least one metal compound selected from the group consisting of a metal-fluoro complex, a metal-fluoro complex containing a hydroxy group, and a metal oxide containing fluorine,
wherein each of the metal compound and the quantum dot contains at least one metal element,
a complex stability constant of the metal-fluoro complex of the at least one metal element contained in the metal compound in an aqueous solution is larger than a complex stability constant of the metal-fluoro complex of the at least one metal element contained in the quantum dot in the aqueous solution, and
the complex stability constant of the metal-fluoro complex of the at least one metal element contained in the metal compound in the aqueous solution is within a range of 0.1 or more and 20.0 or less.

3. The quantum dot composition according to claim 2,
wherein the quantum dot and the organic compound are contained in the quantum dot composition, the quantum dot composition and a solvent are contained in a quantum-dot-composition-containing liquid, and the quantum dot composition is formed by substitution of at least a portion of the organic compound, contained in the quantum-dot-composition-containing liquid, with the metal compound, and then, by removal of the solvent contained in the quantum-dot-composition-containing liquid.

4. The quantum dot composition according to claim 1,
wherein the complex stability constant of the metal-fluoro complex of the at least one metal element contained in the metal compound in the aqueous solution is within a range of 1.2 or more and 19.0 or less.

5. The quantum dot composition according to claim 1,
wherein the complex stability constant of the metal-fluoro complex of the at least one metal element contained in the metal compound in the aqueous solution is larger by 0.1 or more than the complex stability constant of the metal-fluoro complex of the at least one metal element contained in the quantum dot in the aqueous solution.

6. The quantum dot composition according to claim 1,
wherein the complex stability constant of the metal-fluoro complex of the at least one metal element contained in the metal compound in the aqueous solution is larger by 1.5 or more than the complex stability constant of the metal-fluoro complex of the at least one metal element contained in the quantum dot in the aqueous solution.

7. The quantum dot composition according to claim 1,
wherein the complex stability constant of the metal-fluoro complex of the at least one metal element contained in the metal compound in the aqueous solution is larger by 2.5 or more than the complex stability constant of the metal-fluoro complex of the at least one metal element contained in the quantum dot in the aqueous solution.

8. The quantum dot composition according to claim 1,
wherein the quantum dot contains: a core; and a shell having at least one layer.

9. The quantum dot composition according to claim 8,
wherein the core contains at least one of Cdₓ₁Zn₁₋ₓ₁Se_{y1}S_{1-y1} (0≤x1≤1, 0≤y1≤1) or Inₓ₂Ga₁₋ₓ₂P (0≤x2≤1),
the shell contains at least one of metal oxides such as Cdₓ₃Zn₁₋ₓ₃Se_{y3}S_{1-y3} (0≤x3≤1, 0≤y3≤1) or MOₓ₄ (0<x4≤3 wherein M represents a metal element), and
the complex stability constant of the metal-fluoro complex of a metal element contained in a largest amount in the metal compound among the at least one metal element contained in the metal compound in the aqueous solution is larger than a complex stability constant of a metal-fluoro complex of a metal element contained in a largest amount in the shell in the aqueous solution.

10. The quantum dot composition according to claim 1,
wherein the at least one metal element contained in the metal compound is at least one selected from the group consisting of Ti, Sn, V, and Si.

11. The quantum dot composition according to claim 1,
wherein the at least one metal element contained in the metal compound is at least one selected from the group consisting of Ti, Sn, and V.

12. The quantum dot composition according to claim 1,
wherein the metal-fluoro complex contains a metal element that forms the metal oxide by hydrolysis.

13. The quantum dot composition according to claim 1,
wherein the metal-fluoro complex contains at least one selected from the group consisting of TiF₆²⁻, SnF₆²⁻, and VF₆⁻.

14. A quantum-dot-composition-containing liquid containing the quantum dot composition according to claim 1.

15. A light-emitting element comprising a light-emitting layer containing the quantum dot composition according to claim 1.

16. A light-emitting device comprising the light-emitting element according to claim 15.

17. A method for producing a quantum dot composition, the method comprising:
a substituting step of substituting at least a portion of an organic compound with at least one metal compound selected from the group consisting of a metal-fluoro complex, a metal-fluoro complex containing a hydroxy group, and a metal oxide containing fluorine, the organic compound and a quantum dot being contained in an initial quantum dot composition,
wherein each of the quantum dot and the metal compound to be used contains at least one metal element, a complex stability constant of the metal-fluoro complex of the at least one metal element contained in the metal compound in an aqueous solution is larger than a complex stability constant of the metal-fluoro complex of the at least one metal element contained in the quantum dot in the aqueous solution, and the complex stability constant of the metal-fluoro complex of the at least one metal element contained in the metal compound in the aqueous solution is within a range of 0.1 or more and 20.0 or less.

18. The method for producing the quantum dot composition according to claim 17,
wherein the quantum dot and the organic compound are contained in the quantum dot composition, the quantum dot composition and a solvent are contained in a quantum-dot-composition-containing liquid, and the substituting step involves substituting at least a portion of the organic compound, contained in the quantum-dot-composition-containing liquid, with the metal compound, and
the method further comprises a solvent removing step of removing, after the substituting step, the solvent contained in the quantum-dot-composition-containing liquid.
